(19) United States
(12) Patent Application Publication
(10) Pub. No.: US 2026/0343732 A1
(43) Pub. Date: Oct. 29, 2026

(54) WIRING CIRCUIT BOARD

(71) Applicant: NITTO DENKO CORPORATION, Osaka (JP)

(72) Inventors: Takaya KOUCHI, Osaka (JP); Makiko HIRATA, Osaka (JP); Shusaku SHIBATA, Osaka (JP)

(73) Assignee: NITTO DENKO CORPORATION, Osaka (JP)

(21) Appl. No.: 19/650,015

(22) Filed: Apr. 16, 2026

(30) Foreign Application Priority Data
Apr. 25, 2025 (JP) 2025-073352

(51) Int. Cl. H05K 1/02

(52) U.S. Cl. CPC H05K 1/0296

(57) ABSTRACT

A wiring circuit board includes a first insulating layer, a first circuit pattern, a metal support layer insulated from the first circuit pattern by the first insulating layer, and a second circuit pattern independent from the first circuit pattern. The second circuit pattern further includes a metal layer continuous with the metal support layer and a first terminal having a terminal insulating layer disposed at one side of the metal layer in the thickness direction. The first terminal includes a first end disposed away from the metal support layer and a second end disposed between the first end and the metal support layer. The terminal insulating layer is disposed between the first end and the second end.

### CROSS-REFERENCE TO RELATED APPLICATION

The present application claims priority from Japanese Patent Application No. 2025-073352 filed on Apr. 25, 2025, the content of which is hereby incorporated by reference into this application.

### TECHNICAL FIELD

The present disclosure relates to a wiring circuit board.

### BACKGROUND ART

Conventionally, there has been a known wiring circuit board including a metal support layer, a base insulating layer disposed at one side of the metal support layer, and a conductor layer disposed at one side of the base insulating layer (for example, see Patent Document 1 below).

### CITATION LIST

### Patent Document

Patent Document 1: Japanese Unexamined Patent Publication No. 2020-188189

### SUMMARY OF THE INVENTION

### Problem to be solved by the invention

There are considerations of further improvement in the degree of freedom of circuit design in the wiring circuit board as described in Patent Document 1.

The present disclosure provides a wiring circuit board capable of improving the degree of freedom of circuit design.

### Means for solving the problem

The present invention [1] includes a wiring circuit board comprising:
a first insulating layer;
a first circuit pattern disposed at one side of the first insulating layer in a thickness direction of the first insulating layer;
a metal support layer disposed at an opposite side to the first circuit pattern with respect to the first insulating layer in the thickness direction, insulated from the first circuit pattern by the first insulating layer, and supporting the first circuit pattern and the first insulating layer; and
a second circuit pattern independent from the first circuit pattern, wherein the second circuit pattern includes a first terminal, wherein the first terminal includes:
a metal layer continuous with the metal support layer; and
a terminal insulating layer disposed at one side of the metal layer in the thickness direction, wherein the first terminal includes:
   a first end disposed away from the metal support layer; and
   a second end disposed between the first end and the metal support layer, and wherein the terminal insulating layer is disposed between the first end and the second end.

According to such a configuration, the first terminal of the second circuit pattern has a metal layer continuous with the metal support layer.

Therefore, by utilizing a metal support layer that supports the first circuit pattern, it is possible to design a second circuit pattern independent from the first circuit pattern.

As a result, it is possible to improve the degree of freedom of the circuit design.

Further, the metal layer of the first terminal is continuous with the metal support layer. Thus, as compared with the case of forming the second circuit pattern by separating a part of the metal support layer from the metal support layer, it is possible to suppress the reduction in the stiffness of the metal support layer due to the formation of the second circuit pattern.

Furthermore, according to such a configuration, the terminal insulating layer is disposed between the first end and the second end of the first terminal. Therefore, when an electronic component is joined in the first terminal, it is possible to suppress the flow of the solder toward the second end side (metal support layer side), and collect the solder at the side closer to the first end than the terminal insulating layer.

As a result, in the first terminal, it is possible to improve the joint reliability with an electronic component.

The present invention [2] includes the wiring circuit board described in the above-described [1], wherein in the thickness direction, the terminal insulating layer is disposed at least at one side of the metal layer at the second end.

According to such a configuration, when an electronic component is joined in the first terminal, it is possible to suppress the flow of the solder toward the second end side, and collect the solder at the side closer to the first end than the terminal insulating layer.

As a result, in the first terminal, it is possible to improve the joint reliability with an electronic component.

The present invention [3] includes the wiring circuit board described in the above-described [1] or [2], wherein the terminal insulating layer is continuous with the first insulating layer.

According to such a configuration, when an electronic component is joined in the first terminal, it is possible to more surely suppress the flow of the solder toward the second end side (metal support layer side).

As a result, in the first terminal, it is possible to improve the joint reliability with an electronic component.

The present invention [4] includes the wiring circuit board described in the above-described [1] or [2], further comprising:
a second insulating layer covering at least a portion of the first circuit pattern, wherein the terminal insulating layer is continuous with the second insulating layer.

According to such a configuration, when an electronic component is joined in the first terminal, it is possible to more surely suppress the flow of the solder toward the second end side (metal support layer side).

As a result, in the first terminal, it is possible to improve the joint reliability with an electronic component.

The present invention [5] includes the wiring circuit board described in the above-described [4], wherein the terminal insulating layer is continuous with the first insulating layer and the second insulating layer.

According to such a configuration, when an electronic component is joined in the first terminal, it is possible to more surely suppress the flow of the solder toward the second end side (metal support layer side).

As a result, in the first terminal, it is possible to improve the joint reliability with an electronic component.

The present invention [6] includes the wiring circuit board described in any one of the above-described [1] to [5], wherein the terminal insulating layer covers at least the metal layer at the second end, and wherein at least a portion of a one-side surface of the metal layer in the thickness direction is exposed from the terminal insulating layer.

According to such a configuration, when an electronic component is joined in the first terminal, it is possible to utilize the one-side surface of the metal layer as a joint surface, and also collect the solder on the exposed one-side surface of the metal layer by using the terminal insulating layer.

As a result, in the first terminal, it is possible to improve the joint reliability with an electronic component.

The present invention [7] includes the wiring circuit board described in any one of the above-described [1] to [6], wherein the first terminal further includes a terminal covering layer that is made of metal and covers at least a portion of the metal layer.

According to such a configuration, it is possible to protect the metal layer with the terminal covering layer.

The present invention [8] includes the wiring circuit board described in the above-described [7], wherein the terminal insulating layer covers at least the metal layer at the second end, and wherein the terminal covering layer covers a rest of the metal layer.

According to such a configuration, it is possible to protect the metal layer with the terminal insulating layer and the terminal covering layer.

Further, according to such a configuration, when an electronic component is joined in the first terminal, it is possible to utilize the one-side surface of the terminal covering layer as a joint surface, also collect the solder on the one-side surface of the covering layer by using the terminal insulating layer.

As a result, in the first terminal, it is possible to improve the joint reliability with the electronic component.

The present invention [9] includes the wiring circuit board described in the above-described [7] or [8], wherein a thickness of the terminal insulating layer is larger than a thickness of the terminal covering layer.

According to such a configuration, when an electronic component is joined in the first terminal, it is possible to more surely suppress the flow of the solder toward the second end side (metal support layer side) by using the thickness of the terminal insulating layer.

As a result, in the first terminal, it is possible to improve the joint reliability with an electronic component.

The present invention [10] includes the wiring circuit board described in any one of the above-described [1] to [9], further comprising a conductor layer disposed between the first insulating layer and the metal support layer in the thickness direction.

According to such a configuration, it is possible to improve the electrical properties of the wiring circuit board.

The present invention [11] includes the wiring circuit board described in the above-described [10], wherein the first terminal further includes a terminal conductor layer continuous with the conductor layer.

According to such a configuration, by utilizing the conductor layer, it is possible to design a second circuit pattern independent from the first circuit pattern.

As a result, it is possible to improve the conductive performance of the second circuit pattern while improving the degree of freedom of circuit design.

The present invention [12] includes the wiring circuit board described in the above-described [11], wherein the terminal insulating layer covers at least the terminal conductor layer at the second end, and wherein at least a portion of a one-side surface of the terminal conductor layer in the thickness direction is exposed from the terminal insulating layer.

According to such a configuration, when an electronic component is joined in the first terminal, it is possible to utilize the one-side surface of the terminal conductor layer as a joint surface, and also collect the solder on the exposed one-side surface of the terminal conductor layer by using the terminal insulating layer.

As a result, in the first terminal, it is possible to improve the joint reliability with an electronic component.

The present invention [13] includes the wiring circuit board described in the above-described [11] or [12], wherein the first terminal further includes a terminal covering layer that is made of metal and covers at least a portion of the terminal conductor layer.

According to such a configuration, it is possible to protect the terminal conductor layer with the terminal covering layer.

The present invention [14] includes the wiring circuit board described in the above-described [13], wherein the terminal insulating layer covers at least the terminal conductor layer at the second end, and wherein the terminal covering layer covers a rest of the terminal conductor layer.

According to such a configuration, it is possible to protect the terminal conductor layer with the terminal insulating layer and the terminal covering layer.

According to such a configuration, when an electronic component is joined in the first terminal, it is possible to utilize the one-side surface of the terminal covering layer as a joint surface, and also collect the solder on the one-side surface of the terminal covering layer by using the terminal conductor layer.

As a result, in the first terminal, it is possible to improve the joint reliability with an electronic component.

The present invention [15] includes the wiring circuit board described in the above-described [13] or [14], wherein a thickness of the terminal insulating layer is larger than a thickness of the terminal covering layer.

According to such a configuration, when an electronic component is joined in the first terminal, it is possible to more surely suppress the flow of the solder toward the second end side (metal support layer side) by using the thickness of the terminal insulating layer.

As a result, in the first terminal, it is possible to further improve the joint reliability with an electronic component.

### EFFECTS OF THE INVENTION

According to the wiring circuit board of the present disclosure, it is possible to improve the degree of freedom of the circuit design.

### BRIEF DESCRIPTION OF THE DRAWINGS

FIG. 1 is a plan view of one embodiment of the wiring circuit board of the present disclosure. In FIG. 1, the second insulating layer, the covering layer, and the terminal covering layer are omitted.

FIG. 2A is a cross-sectional view of the wiring circuit board shown in FIG. 1, taken along line A-A. FIG. 2 B is a cross-sectional view of the wiring circuit board shown in FIG. 1, taken along line B-B.

FIGS. 3A - 3C are process diagrams showing the steps of producing the wiring circuit board shown in FIGS. 1, and 3A shows the conductor layer forming step, FIG. 3B shows the first insulating layer forming step, and FIG. 3C shows the conductor pattern forming step.

FIGS. 4A - 4C are process diagrams showing the steps of producing the wiring circuit board, following FIG. 3C, FIG. 4A shows the second insulating layer forming step, FIG. 4B shows the outer shape trimming step, and FIG. 4C shows the cover layer forming step.

FIGS. 5A and 5B show a modified example (1) of the wiring circuit board, FIG. 5A is a cross-sectional view corresponding to the A-A cross-sectional view of FIG. 2A, and FIG. 5B is a cross-sectional view corresponding to the B-B cross-sectional view of FIG. 2B.

FIG. 6 is a cross-sectional view of a modified example (2) of the wiring circuit board.

FIG. 7 is a cross-sectional view of a modified example (3) of the wiring circuit board.

FIGS. 8A and 8B show a modified example (4) of the wiring circuit board, FIG. 8A is a cross-sectional view corresponding to the A-A cross-sectional view of FIG. 2A, and FIG. 8B is a cross-sectional view corresponding to the B-B cross-sectional view of FIG. 2B.

FIG. 9 is a cross-sectional view of a modified example (5) of the wiring circuit board.

FIG. 10 is a cross-sectional view of a modified example (6) of the wiring circuit board.

FIG. 11 is a cross-sectional view of a modified example (7) of the wiring circuit board.

FIG. 12 is a cross-sectional view of a modified example (8) of the wiring circuit board.

FIG. 13 is a cross-sectional view of a modified example (9) of the wiring circuit board.

FIG. 14 is a cross-sectional view of a modified example (10) of the wiring circuit board.

FIG. 15 is a cross-sectional view of a modified example (11) of the wiring circuit board.

FIG. 16 is a cross-sectional view of a modified example (12) of the wiring circuit board.

FIGS. 17A and 17B show a modified example (13) of the wiring circuit board, FIG. 17A is a plan view of the modified example (13) of the wiring circuit board, and FIG. 17B is a cross-sectional view of FIG. 17A, taken along line A-A.

### DESCRIPTION OF THE EMBODIMENT

### 1. Wiring Circuit Board

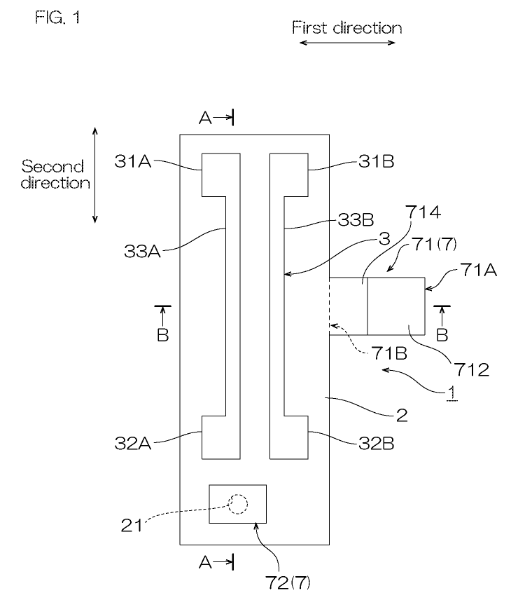

As shown in FIG. 1, in the present embodiment, a wiring circuit board 1 extends in a first direction and a second direction. The first direction is a direction in which a plurality of terminals 31A and 31B are aligned. The terminals 31A and 31B are described later. The second direction is perpendicular to the first direction. The shape of the wiring circuit board 1 is not limited to the present embodiment.

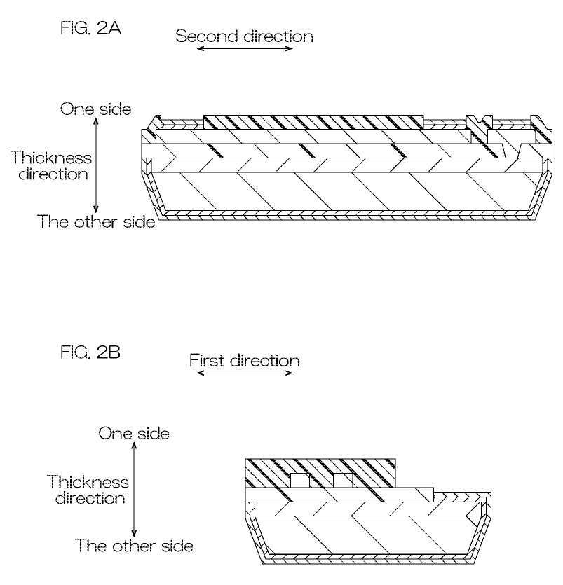

As shown in FIGS. 2A and 2B, the wiring circuit board 1 includes a first insulating layer 2 as an example of an insulating layer, a first circuit pattern 3 (see FIG. 1), a metal support layer 4, a conductor layer 5, a covering layer 6, a second circuit pattern 7 (see FIG. 1), and a second insulating layer 8.

### (1) First Insulating Layer

The first insulating layer 2 insulates the metal support layer 4 and the conductor layer 5 from the first circuit pattern 3. The first insulating layer 2 is made of resin. Examples of the resin include polyimide, maleimide, epoxy resin, polybenzoxazole, and polyester. The first insulating layer 2 has a through hole 21.

### (2) First Circuit Pattern

The first circuit pattern 3 is disposed at one side of the first insulating layer 2 in a thickness direction of the first insulating layer 2. The thickness direction is perpendicular to the first direction and the second direction. The first circuit pattern 3 is disposed on a one-side surface of the first insulating layer 2 in the thickness direction.

As shown in FIG. 1, the first circuit pattern 3 includes a plurality of terminals 31A and 31B, a plurality of terminals 32A and 32B, and a plurality of wires 33A and 33B. The terminals 31A and 31B are aligned in the first direction. The terminal 31B is disposed away from the terminal 31A in the first direction. Each of the terminal 31A and terminal 31B extends in the first direction and the second direction. Each of the terminals 31A and 31B has a substantially rectangular shape.

As shown in FIG. 2A, the terminal 31A includes a conductor layer 311. Although not shown, the terminal 31B includes a conductor layer 311. Each of the terminals 31A and 31B, if required, may have a covering layer 312.

The conductor layer 311 is disposed on the one-side surface of the first insulating layer 2 in the thickness direction. The conductor layer 311 is made of metal. Examples of the metal include copper, silver, gold, iron, aluminum, chromium, and an alloy thereof. From the viewpoint of obtaining good electrical properties, the conductor layer 311 is preferably made of copper.

Between the conductor layer 311 and the second insulating layer 8, preferably, a protective metal layer that protects the conductor layer 311 is disposed. The protective metal layer is made of metal. Examples of the material for the protective metal layer include chromium, nickel, titanium, and an alloy thereof.

The protective metal layer is not shown.

The covering layer 312 covers a surface of the conductor layer 311. In the present embodiment, the covering layer 312 covers a central portion of a one-side surface of the conductor layer 311 in the thickness direction (a portion that is not covered by the second insulating layer 8). The covering layer 312 has a surface layer 312A. The surface layer 312A is made of a metal different from the conductor layer 311. The surface layer 312A is made, for example, of gold. The covering layer 312 preferably has an intermediate layer 312B. The covering layer 312 may not have an intermediate layer 312B. The intermediate layer 312B is disposed between the conductor layer 311 and the surface layer 312A. The intermediate layer 312B is made of a metal different from the conductor layer 311 and the surface layer 312A. The intermediate layer 312B is made, for example, of nickel.

As shown in FIG. 1, the terminal 32A is disposed away from the terminal 31A in the second direction. The terminal 32B is disposed away from the terminal 31B in the second direction. The terminals 32A and 32B are aligned in the first direction. The terminal 32B is disposed away from the terminal 32A in the first direction. Each of the terminals 32A and 32B, for example, has a substantially rectangular shape. The descriptions of the terminals 32A and 32B are the same as those of the terminals 31A and 31B. Therefore, the descriptions of the terminals 32A and 32B are omitted.

The wire 33A electrically connects the terminal 31 A and the terminal 32 A. One end of the wire 33A is connected to the terminal 31A. Specifically, one end of the wire 33A is connected to the conductor layer 311 of the terminal 31A (see FIG. 2A). The other end of the wire 33A is connected to the terminal 32A. Specifically, the other end of the wire 33A is connected to the conductor layer 311 of the terminal 32A (see FIG. 2A).

The wire 33B electrically connects the terminal 31B and the terminal 32B. One end of the wire 33B is connected to the terminal 31B. The other end of the wire 33 B is connected to the terminal 32 B.

The wires 33A and 33B are made of the same material as the conductor layer 311.

### (3) Metal Support Layer

As shown in FIGS. 2A and 2B, the metal support layer 4 is disposed at the other side of the first insulating layer 2 in the thickness direction. The metal support layer 4 is disposed at the opposite side to the first circuit pattern 3 with respect to the first insulating layer 2 in the thickness direction. The metal support layer 4 is insulated from the first circuit pattern 3 by the first insulating layer 2. The metal support layer 4 supports the first circuit pattern 3 and the first insulating layer 2. The entire metal support layer 4 overlaps the first insulating layer 2 in the thickness direction. Examples of the material for the metal support layer 4 include stainless steel and a copper alloy.

### (4) Conductor Layer

The conductor layer 5 is disposed at the other side of the first insulating layer 2 and one side of the metal support layer 4 in the thickness direction. In other words, the conductor layer 5 is disposed between the first insulating layer 2 and the metal support layer 4 in the thickness direction. The conductor layer 5 is in contact with an other-side surface of the first insulating layer 2 and in contact with a one-side surface of the metal support layer 4 in the thickness direction. The conductor layer 5 is disposed at the opposite side to the first circuit pattern 3 with respect to the first insulating layer 2 in the thickness direction. The conductor layer 5 is insulated from the first circuit pattern 3 by the first insulating layer 2. As shown in FIG. 2A, the conductor layer 5 extends from one end to the other end of the metal support layer 4 in the second direction, and, as shown in FIG. 2B, extends from one end to the other end of the metal support layer 4 in the first direction. The conductor layer 5 does not have a wiring pattern. The entire conductor layer 5 overlaps the first insulating layer 2 in the thickness direction. The conductor layer 5 overlaps the entire first circuit pattern 3 in the thickness direction. The conductivity of the conductor layer 5 is higher than the conductivity of the metal support layer 4. The conductor layer 5 is made, for example, of copper.

Between the metal support layer 4 and the conductor layer 5, a joint layer that joins the metal support layer 4 and the conductor layer 5 may be disposed. The joint layer is made of metal. Examples of the material for the joint layer include chromium, nickel, titanium, and an alloy thereof.

Further, between the conductor layer 5 and the first insulating layer 2, preferably, a protective metal layer that protects the conductor layer 5 is disposed. The protective metal layer is made of metal. Examples of the material for the protective metal layer include chromium, nickel, titanium, and an alloy thereof.

The joint layer and the protective metal layer are not shown.

### (5) Covering Layer

The covering layer 6 covers the metal support layer 4. Specifically, the covering layer 6 covers the entire other-side surface S1 of the metal support layer 4 in the thickness direction. Further, the covering layer 6 covers an entire end surface S2 of the metal support layer 4 and an entire end surface S3 of the conductor layer 5. In the present embodiment, the end surface S3 of the conductor layer 5 is continuous with the end surface S2 of the metal support layer 4 in the thickness direction. The end surface S3 of the conductor layer 5 is discontinuous with an end surface of the first insulating layer 2. The covering layer 6 has a surface layer 61. The covering layer 6 preferably has an intermediate layer 62. The covering layer 6 may not have an intermediate layer 62. The intermediate layer 62 is disposed between the metal support layer 4 and the surface layer 61, and between the conductor layer 5 and the surface layer 61. The covering layer 6 is made of metal. Specifically, the surface layer 61 is made of a metal different from the metal support layer 4 and the conductor layer 5. The surface layer 61 is made, for example, of gold. The intermediate layer 62 is made of a metal different from the metal support layer 4, the conductor layer 5, and the surface layer 61. The intermediate layer 62 is made, for example, of nickel.

### (6) Second Circuit Pattern

As shown in FIG. 1, the second circuit pattern 7 is independent from the first circuit pattern 3. The second circuit pattern 7 includes a first terminal 71 and a second terminal 72. The first terminal 71 and the second terminal 72 are electrically connected through the conductor layer 5 (see FIGS. 2A and 2B), and thus the second circuit pattern 7 functions as an electrical circuit independent from the first circuit pattern 3.

### (6-1) First Terminal

In the present embodiment, the first terminal 71 is disposed between the terminal 31B and the terminal 32B in the second direction. In other words, the first terminal 71 is aligned with the wires 33A and 33B in the first direction. The first terminal 71 is disposed at the opposite side to the wire 33A with respect to the wire 33B in the first direction. The first terminal 71 has a prismatic shape extending in the first direction. The position and shape of the first terminal 71 are not limited to the present embodiment.

The first terminal 71 does not overlap the first insulating layer 2 in the thickness direction. The first terminal 71 does not overlap the second insulating layer 8 in the thickness direction, either.

As shown in FIG. 2B, the first terminal 71 is continuous with the metal support layers 4. Therefore, the first terminal 71 is electrically connected to the metal support layer 4.

Further, as shown in FIG. 2B, the first terminal 71 includes a first end 71A which is disposed away from the metal support layer 4 and a second end 71B which is disposed between the first end 71A and the metal support layer 4. In other words, the first end 71A is spaced apart from the metal support layer 4 in a first direction. The second end 71B is spaced apart from the first end 71A toward the metal support layer 4 side in the first direction. The second end 71B may be connected to the metal support layer 4.

As shown in FIG. 2B, the first terminal 71 includes a metal layer 711, a terminal conductor layer 712, a terminal covering layer 713, and a terminal insulating layer 714.

The metal layer 711 is continuous with the metal support layer 4. The metal layer 711 forms a single layer with the metal support layer 4. The metal layer 711 is made of the same material as the metal support layer 4. In the present embodiment, the metal layer 711 extends from the end portion of the metal support layer 4 at the opposite side to the wire 33A with respect to the wire 33B toward the opposite side to the wire 33A with respect to the wire 33B in the first direction.

The terminal conductor layer 712 is disposed at one side of the metal layer 711 in the thickness direction. The terminal conductor layer 712 is disposed on a one-side surface of the metal layer 711 in the thickness direction. The terminal conductor layer 712 is continuous with the conductor layer 5. The terminal conductor layer 712 forms a single layer with the conductor layer 5. The terminal conductor layer 712 is made of the same material as the conductor layer 5. In the present embodiment, the terminal conductor layer 712 extends from the end portion of the conductor layer 5 at the opposite side to the wire 33A with respect to the wire 33B toward the opposite side to the wire 33A with respect to the wire 33B in the first direction.

Between the metal layer 711 and the terminal conductor layer 712, a joint layer that joins the metal layer 711 and the terminal conductor layer 712 may be disposed. The joint layer is made of metal. Examples of the material for the joint layer include chromium, nickel, titanium, and an alloy thereof.

Furthermore, between the terminal conductor layer 712 and the terminal insulating layer 714, preferably, a protective metal layer that protects the terminal conductor layer 712 is disposed. The protective metal layer is made of metal. Examples of the material for the protective metal layer include chromium, nickel, titanium, and an alloy thereof.

The joint layer and the protective metal layer are not shown.

In the thickness direction, the terminal covering layer 713 covers at least a portion of the terminal conductor layer 712. The terminal covering layer 713 covers at least a portion of a one-side surface S11 of the terminal conductor layer 712 in the thickness direction. In the thickness direction, the terminal covering layer 713 covers a rest of the terminal conductor layer 712. The rest of the terminal conductor layer 712 is a portion other than the portion covered by the terminal insulating layer 714 on the one-side surface S11 of the terminal conductor layer 712. In other words, in the thickness direction, the terminal covering layer 713 covers the entire one-side surface S11 of the terminal conductor layer 712 exposed from the terminal insulating layer 714. In the present embodiment, in the thickness direction, the terminal covering layer 713 covers at least the one-side surface S11 of the terminal conductor layer 712 at the first end 71A. In the thickness direction, the terminal covering layer 713 does not cover the one-side surface S11 of the terminal conductor layer 712 at the second end 71B. The terminal covering layer 713 covers the entire other-side surface S12 of the metal layer 711 in the thickness direction, the entire end surface S13 of the terminal conductor layer 712, and the entire end surface S14 of the metal layer 711. In the present embodiment, the end surface S13 of the terminal conductor layer 712 is continuous with the end surface S14 of the metal layer 711 in the thickness direction.

The terminal covering layer 713 includes a surface layer 713A. The terminal covering layer 713 preferably includes an intermediate layer 713B. The terminal covering layer 713 may not have an intermediate layer 713B. The intermediate layer 713B is disposed between the metal layer 711 and the surface layer 713A and between the terminal conductor layer 712 and the surface layer 713A. The terminal covering layer 713 is continuous with the covering layer 6. In detail, the surface layer 713A is continuous with the surface layer 61 of the cover layer 6. The intermediate layer 713B is continuous with the intermediate layer 62 of the cover layer 6. The surface layer 713A is made of a metal different from the metal layer 711 and the terminal conductor layer 712. The surface layer 713A is made of the same material as the surface layer 61 of the cover layer 6. The surface layer 713A is made, for example, of gold. The intermediate layer 713B is made of a metal different from the metal layer 711, the terminal conductor layer 712, and the surface layer 713A. The intermediate layer 713B is made of the same material as the intermediate layer 62 of the covering layer 6. The intermediate layer 713B is made, for example, of nickel. In other words, the terminal covering layer 713 is made of metal.

The terminal insulating layer 714 is disposed at one side of the metal layer 711 in the thickness direction. In detail, in the thickness direction, the terminal insulating layer 714 is disposed at least at one side of the metal layer 711 at the second end 71B.

The terminal insulating layer 714 covers at least a portion of the terminal conductor layer 712 in the thickness direction. The terminal insulating layer 714 covers at least a portion of the one-side surface S11 of the terminal conductor layer 712 in the thickness direction. In the thickness direction, the terminal insulating layer 714 covers at least the one-side surface S11 of the terminal conductor layer 712 at the second end 71B. In the present embodiment, in the thickness direction, the terminal insulating layer 714 does not cover the one-side surface S11 of the terminal conductor layer 712 at the first end 71A. At least a portion of the one-side surface S11 of the terminal conductor layer 712 in the thickness direction is exposed from the terminal insulating layer 714.

In the present embodiment, the terminal insulating layer 714 is continuous with the first insulating layer 2. The terminal insulating layer 714 forms a single layer with the first insulating layer 2. The terminal insulating layer 714 is made of the same material as the first insulating layer 2. The thickness of the terminal insulating layer 714 may be the same as or different from the thickness of the first insulating layer 2. In the present embodiment, in the first direction, the terminal insulating layer 714 extends from the end portion of the first insulating layer 2 at the opposite side to the wire 33A with respect to the wire 33B toward the opposite side to the wire 33A with respect to the wire 33B.

The thickness of the terminal insulating layer 714 is preferably larger than the thickness of the terminal covering layer 713.

Further, in the present embodiment, as shown in FIG. 1, the terminal insulating layer 714 is substantially rectangular when viewed from the thickness direction. In other words, the terminal insulating layer 714 is substantially rectangular in a plan view.

### (6-2) Second Terminal

As shown in FIG. 1, in the present embodiment, the second terminal 72 is disposed in the other end portion of the wiring circuit board 1 in the second direction. The second terminal 72 has a substantially rectangular shape. The position and shape of the second terminal 72 are not limited to the present embodiment.

As shown in 2A, the second terminal 72 is disposed at one side of the first insulating layer 2 in the thickness direction. The second terminal 72 is electrically connected to the conductor layer 5 through the through hole 21 of the first insulating layer 2.

The second terminal 72 has a conductor layer 721 in the same manner as the terminal 31A of the first circuit pattern 3.

The second terminal 72 may have a covering layer 722, if necessary.

The conductor layer 721 is disposed on the one-side surface of the first insulating layer 2 in the thickness direction. The conductor layer 721 is made of the same material as the terminal 31A of the first circuit pattern 3.

Between the conductor layer 721 and the second insulating layer 8, preferably a protective metal layer that protects the conductor layer 721 is disposed. The protective metal layer is made of metal. Examples of the material for the protective metal layer include chromium, nickel, titanium, and an alloy thereof.

The protective metal layer is not shown.

The covering layer 722 covers the surface of the conductor layer 721. In the present embodiment, the covering layer 722 covers a central portion of a one-side surface of the conductor layer 721 in the thickness direction (a portion that is not covered by the second insulating layer 8). The covering layer 722 has a surface layer 722A. The surface layer 722A is made, for example, of gold. The covering layer 722 preferably has an intermediate layer 722B. The covering layer 722 may not have an intermediate layer 722B. The intermediate layer 722B is disposed between the conductor layer 721 and the surface layer 722A. The intermediate layer 722B is made, for example, of nickel.

### (7) Secondary Insulating Layer

The second insulating layer 8 is disposed at one side of the first insulating layer 2 in the thickness direction. The second insulating layer 8 is disposed on the one-side surface of the first insulating layer 2 in the thickness direction. The second insulating layer 8 is made of resin. Examples of the resin include polyimide, maleimide, epoxy resin, polybenzoxazole, and polyester. The second insulating layer 8 covers at least a portion of the first circuit pattern 3. The second insulating layer 8 covers the wires 33A and 33B (see FIG. 1). The second insulating layer 8 may cover the peripheral edge portion of each of the terminals 31A, 31B, 32A, 32B and the second terminal 72. The second insulating layer 8 does not cover the central portion of each of the terminals 31A, 31B, 32A, 32B and the second terminal 72.

### 2. Method of Producing Wiring Circuit Board

Next, a method of producing the wiring circuit board 1 is described.

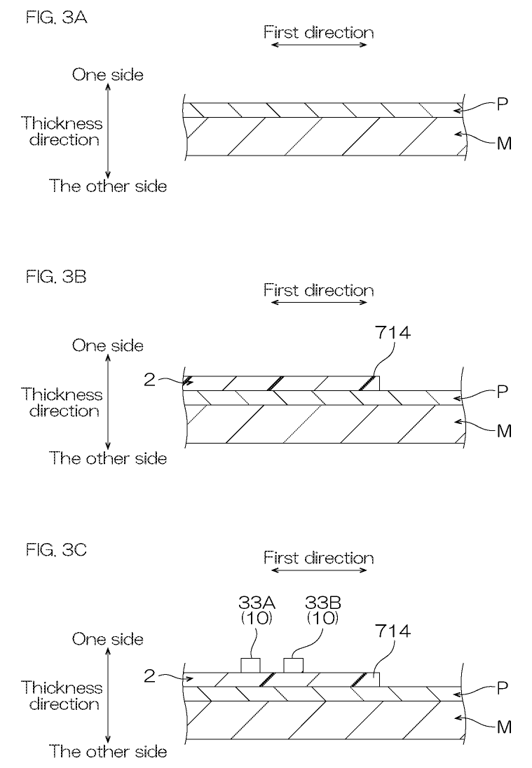

The method of producing the wiring circuit board 1 includes a conductor layer forming step (see FIG. 3A), a first insulating layer forming step (see FIG. 3B), a conductor pattern forming step (see FIG. 3C), a second insulating layer forming step (see FIG. 4A), an outer shape trimming step (see FIG. 4B), and a covering layer forming step (see FIG. 4C).

### (1) Conductor Layer Forming Step

As shown in FIG. 3A, in the conductor layer forming step, a conductor layer P is formed on the entire surface of a metallic substrate M, for example, by electrolytic plating.

In detail, first, in the thickness direction, the above-described joint layer is formed on a one-side surface of the substrate M. The joint layer is formed, for example, by sputtering.

Next, a conductor layer P is formed on the joint layer, for example, by electrolytic plating.

When a joint layer is not formed, a conductor layer P is formed on the one-side surface of the substrate M, for example, by electrolytic plating.

### (2) First Insulating Layer Forming Step

Next, as shown in FIG. 3B, in the first insulating layer forming step, a first insulating layer 2 and a terminal insulating layer 714 are formed on a one-side surface of the conductor layer P.

In detail, in the first insulating layer forming step, first, the above-described protective metal layer is formed on the one-side surface of the conductor layer P in the thickness direction. The protective metal layer is formed, for example, by sputtering.

Next, a solution (varnish) of a photosensitive resin is applied onto the conductor layer P and dried to form a coating film of the photosensitive resin. Next, the coating film of the photosensitive resin is exposed to light and developed. Thus, a first insulating layer 2 and a terminal insulating layer 714 are obtained.

In detail, after the coating film of the photosensitive resin is formed on the conductor layer P, a portion where the first insulating layer 2 and the terminal insulating layer 714 are not formed is shielded, for example, by a photomask. Thereafter, when the development is carried out, the light-shielded portion of the coating film of the photosensitive resin is removed, and thus the first insulating layer 2 or the terminal insulating layer 714 is not formed.

In the thickness direction, the first insulating layer 2 and the terminal insulating layer 714 are not formed at least in a portion of the one-side surface of the conductor layer P. Specifically, as shown in FIG. 3B, in the thickness direction, the terminal insulating layer 714 is not formed on the one-side surface of the conductor layer P on which a terminal covering layer 713 is to be disposed. In other words, in the thickness direction, the coating film of the photosensitive resin is removed on the one-side surface of the conductor layer P on which a terminal covering layer 713 is to be disposed. Further, although not shown, the coating film of the photosensitive resin is also removed at a position where a through hole 21 is to be formed. By that, a through hole 21 is formed.

### (3) Conductive Pattern Forming Step

Next, as shown in FIG. 3C, in the conductor pattern forming step, a conductor pattern 10 is formed on the first insulating layer 2. The conductor pattern 10 includes the conductor layer 311 of each of the terminals 31A, 31B, 32A, 32B, the wires 33A and 33B, and the conductor layer 721 of the second terminal 72.

In detail, first, in the thickness direction, a seed layer is formed on a one-side surface of the first insulating layer 2 and on the one-side surface of the conductor layer P. The seed layer is formed, for example, by sputtering. Examples of the material for the seed layer include chromium, copper, nickel, titanium, and an alloy thereof.

Next, the seed layer is covered with a plating resist.

Next, the plating resist is exposed to light and developed. Then, the plating resist of the portion where a conductor pattern 10 is to be formed is removed, and the seed layer is exposed in the portion where a conductor pattern 10 is to be formed. On the other hand, the plating resist of the portion where a conductive pattern 10 is not formed remains.

Next, a conductive pattern 10 is formed on the exposed seed layer by electrolytic plating. After the electrolytic plating is completed, the plating resist is released, and the seed layer exposed due to the release of the plating resist is removed by etching.

Thus, a conductor pattern 10 is formed on the first insulating layer 2.

### (4) Second Insulating Layer Forming Step

Next, as shown in FIG. 4A, in the second insulating layer forming step, a second insulating layer 8 is formed on the first insulating layer 2.

In detail, in the second insulating layer forming step, first, the above-described protective metal layer is formed on the exposed surface of the conducting pattern 10 in the thickness direction. The protective metal layer is formed, for example, by electroless plating.

Next, a solution (varnish) of the photosensitive resin is applied on the conductor pattern 10, the first insulating layer 2, and the conductor layer P, and dried to form a coating film of the photosensitive resin.

Next, the coating film of the photosensitive resin is exposed to light and developed. Thus, a second insulating layer 8 is formed on the first insulating layer 2.

In detail, after the coating film of the photosensitive resin is formed on the conducting pattern 10, the first insulating layer 2, and the conductor layer P, a portion where the second insulating layer 8 is not formed is shielded, for example, by a photomask.

Thereafter, when the development is carried out, the light-shielded portion of the coating film of the photosensitive resin is removed, and thus the second insulating layer 8 is not formed thereon.

### (5) Outer Shape Trimming Step

Next, as shown in FIG. 4B, in the outer shape trimming step, the substrate M and the conductor layer P are etched to form a metal support layer 4, a conductor layer 5, a metal layer 711, and a terminal conductor layer 712.

### (6) Covering Layer Forming Step

Next, as shown in FIG. 4C, in the covering layer forming step, for example, electroless nickel plating and electroless gold plating are carried out in order to simultaneously form a covering layer 312, a covering layer 722, a covering layer 6, and a terminal covering layer 713. The covering layer 312, the covering layer 722, the covering layer 6, and the terminal covering layer 713 may be formed by electroplating.

As described above, the above-described wiring circuit board 1 is obtained.

### 3. Operations and Effects

(1) According to the wiring circuit board 1, as shown in FIGS. 1 and 2B, the first terminal 71 of the second circuit pattern 7 includes the metal layer 711 continuous with the metal support layer 4.

Therefore, by utilizing the metal support layer 4 supporting the first circuit pattern 3, it is possible to design the second circuit pattern 7 independent from the first circuit pattern 3.

As a result, it is possible to improve the degree of freedom of the circuit design.

Further, the metal layer 711 of the first terminal 71 is continuous with the metal support layer 4, and thus it is possible to suppress the reduction in the stiffness of the metal support layer 4 due to the formation of the second circuit pattern 7, as compared with the case of forming the second circuit pattern 7 by separating a portion of the metal support layer 4 from the metal support layer 4.

(2) According to the wiring circuit board 1, as shown in FIG. 2B, the terminal insulating layer 714 is disposed between the first end 71A and the second end 71B of the first terminal 71.

Therefore, when an electronic component is joined in the first terminal 71, it is possible to suppress the flow of the solder toward the second end 71B side (metal support layer 4 side), and to collect the solder at the side closer to the first end 71A than the terminal insulating layer 714.

As a result, in the first terminal 71, it is possible to improve the joint reliability with the electronic component.

(3) According to the wiring circuit board 1, as shown in FIG. 2B, the terminal insulating layer 714 is disposed at least at one side of the metal layer 711 at the second end 71B.

Therefore, when an electronic component is joined in the first terminal 71, it is possible to suppress the flow of the solder toward the second end 71B side, and to collect the solder at the side closer to the first end 71A than the terminal insulating layer 714.

As a result, in the first terminal 71, it is possible to improve the joint reliability with the electronic component.

(4) According to the wiring circuit board 1, as shown in FIG. 2B, the terminal insulating layer 714 is continuous with the first insulating layer 2.

Therefore, when an electronic component is joined in the first terminal 71, it is possible to more reliably suppress the flow of the solder toward the second end 71B side (metal support layer 4 side).

As a result, in the first terminal 71, it is possible to improve the joint reliability with the electronic component.

(5) As shown in FIGS. 2A and 2B, the wiring circuit board 1 includes the conductor layer 5. The conductor layer 5 is disposed between the first insulating layer 2 and the metal support layer 4 in the thickness direction.

Therefore, it is possible to improve the electrical properties of the wiring circuit board 1.

(6) According to the wiring circuit board 1, as shown in FIG. 2B, the first terminal 71 includes a terminal conductor layer 712 continuous with the conductor layer 5.

Therefore, by utilizing the conductor layer 5, it is possible to design the second circuit pattern 7 independent from the first circuit pattern 3.

As a result, it is possible to improve the conductive performance of the second circuit pattern 7 while improving the degree of freedom of the circuit design.

(7) According to the wiring circuit board 1, as shown in FIG. 2B, the first terminal 71 includes the terminal covering layer 713 that covers at least a portion of the terminal conductor layer 712.

Therefore, the terminal conductor layer 712 can be protected by the terminal covering layer 713.

(8) According to the wiring circuit board 1, as shown in FIG. 2B, the terminal insulating layer 714 covers at least the terminal conductor layer 712 at the second end 71B, and the terminal covering layer 713 covers the rest of the terminal conductor layer 712.

Therefore, the terminal conductor layer 712 can be protected by the terminal insulating layer 714 and the terminal covering layer 713.

Further, according to such a configuration, when an electronic component is joined in the first terminal 71, it is possible to utilize the one-side surface of the terminal covering layer 713 as a joint surface, and to collect the solder on the one-side surface of the covering layer 713 by using the terminal insulating layer 714.

As a result, in the first terminal 71, it is possible to improve the joint reliability with the electronic component.

(9) According to the wiring circuit board 1, as shown in FIG. 2B, the thickness of the terminal insulating layer 714 is larger than the thickness of the terminal covering layer 713.

Therefore, the terminal conductor layer 712 can be protected by the terminal insulating layer 714 and the terminal covering layer 713.

Further, according to such a configuration, when an electronic component is joined in the first terminal 71, it is possible to more reliably suppress the flow of the solder toward the second end 71B side (metal support layer 4 side) by using the thickness of the terminal insulating layer 714.

As a result, in the first terminal 71, it is possible to further improve the joint reliability with the electronic component.

### 4. Modified Examples

Modified examples are described. In the modified examples, the same members as in the above-described embodiment are denoted by the same reference numerals, and the descriptions thereof are omitted.

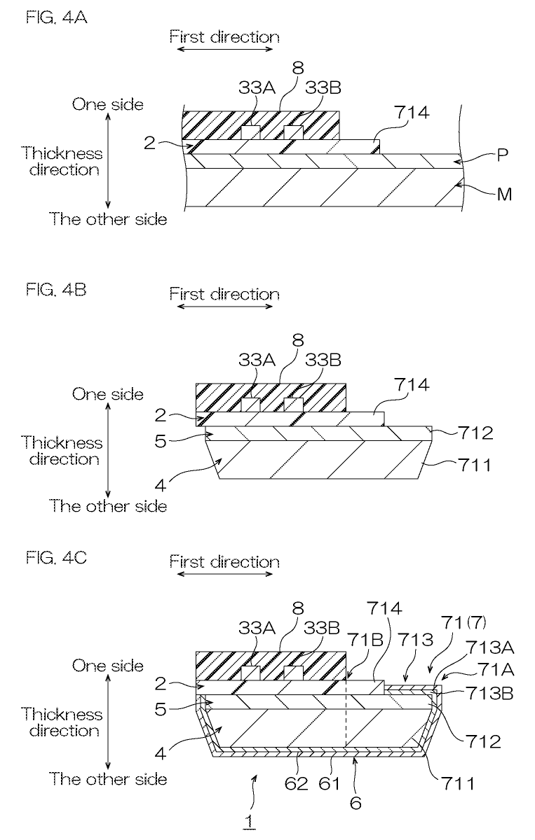

(1) As shown in FIG. 5A, the wiring circuit board 1 may not have a conductor layer 5. In this case, the metal support layer 4 is in contact with the other-side surface of the first insulating layer 2 in the thickness direction.

Further, as shown in FIG. 5B, the first terminal 71 may not include a terminal conductor layer 712 while including a metal layer 711, a terminal covering layer 713, and a terminal insulating layer 714.

In the thickness direction, the terminal covering layer 713 covers at least a portion of the metal layer 711. The terminal covering layer 713 covers at least a portion of a one-side surface S15 of the metal layer 711 in the thickness direction. In the thickness direction, the terminal covering layer 713 covers a rest of the metal layer 711. The rest of the metal layer 711 is a portion other than the portion covered by the terminal insulating layer 714 on the one-side surface S15 of the terminal conductor layer 712. In other words, in the thickness direction, the terminal covering layer 713 covers the entire portion of the one-side surface S15 of the metal layer 711 exposed from the terminal insulating layer 714. In this modified example, in the thickness direction, the terminal covering layer 713 covers at least the one-side surface S15 of the metal layer 711 in the first end 71A. In the thickness direction, the terminal covering layer 713 does not cover the one-side surface S15 of the metal layer 711 at the second end 71B. The terminal covering layer 713 covers an entire other-side surface S12 of the metal layer 711 in the thickness direction and an entire end surface S14 of the metal layer 711.

The terminal insulating layer 714 covers at least a portion of the metal layer 711 in the thickness direction. The terminal insulating layer 714 covers at least a portion of the one-side surface S15 of the metal layer 711 in the thickness direction. In the thickness direction, the terminal insulating layer 714 covers at least the one-side surface S15 of the metal layer 711 at the second end 71B. In this modified example, in the thickness direction, the terminal insulating layer 714 does not cover the one-side surface S15 of the metal layer 711 at the first end 71A. At least a portion of the one-side surface S15 of the metal layer 711 in the thickness-direction is exposed from the terminal insulating layer 714.

As shown in FIG. 5A, when the wiring circuit board 1 does not have a conductor layer 5, the second terminal 72 is electrically connected to the metal support layer 4 through the through hole 21 of the first insulating layer 2.

Thus, the first terminal 71 and the second terminal 72 can be electrically connected through the metal support layer 4.

According to the wiring circuit board 1, as shown in FIG. 5B, the terminal insulating layer 714 covers at least the metal layer 711 at the second end 71B, and the terminal covering layer 713 covers the rest of the metal layer 711. Therefore, it is possible to protect the metal layer with the terminal insulating layer and the terminal covering layer.

Further, according to such a wiring circuit board 1, when an electronic component is joined in the first terminal 71, it is possible to utilize the one-side surface of the terminal covering layer 713 as a joint surface, and to collect the solder on the one-side surface of the covering layer 713 by using the terminal insulating layer 714. As a result, in the first terminal 71, it is possible to improve the joint reliability with the electronic component.

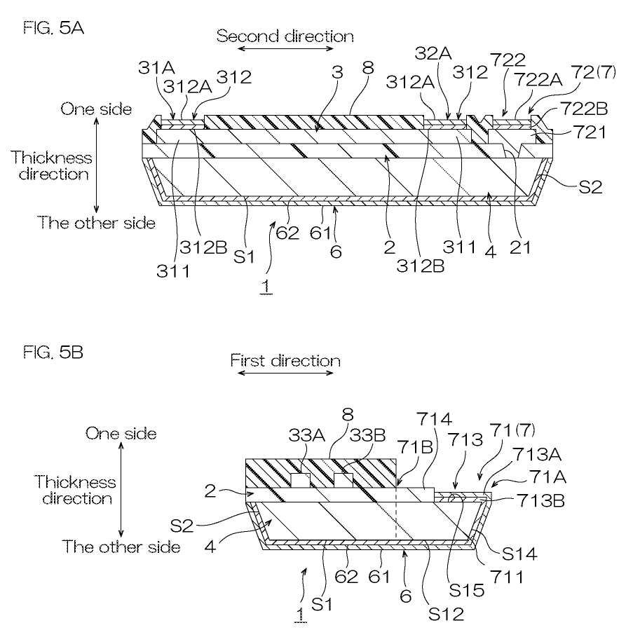

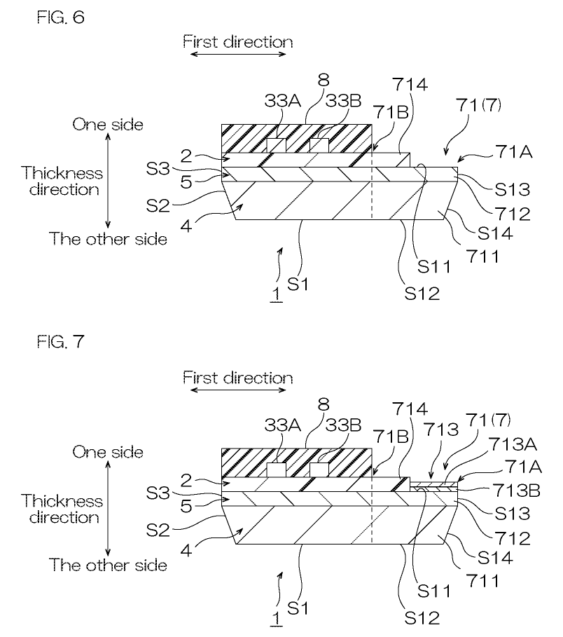

(2) As shown in FIG. 6, the wiring circuit board 1 may not have a covering layer 6. Furthermore, the first terminal 71 may not have a terminal covering layer 713 while including a metal layer 711, a terminal conductor layer 712, and a terminal insulating layer 714.

The terminal insulating layer 714 covers at least a portion of the terminal conductor layer 712 in the thickness direction. The terminal insulating layer 714 covers at least a portion of the one-side surface S11 of the terminal conductor layer 712 in the thickness direction. In the thickness direction, the terminal insulating layer 714 covers at least the one-side surface S11 of the terminal conductor layer 712 at the second end 71B. At least a portion of the one-side surface S11 of the terminal conductor layer 712 in the thickness direction is exposed from the terminal insulating layer 714.

When the wiring circuit board 1 does not have a covering layer 6, the covering layer forming step may be carried out after the second insulating layer forming step before the outer shape trimming step.

According to the wiring circuit board 1, as shown in FIG. 6, the terminal insulating layer 714 covers at least the metal layer 711 at the second end 71B. Then, at least a portion of the one-side surface of the metal layer 711 in the thickness direction is exposed from the terminal insulating layer 714. Therefore, when an electronic component is joined in the first terminal 71, it is possible to utilize the one-side surface of the metal layer 711 as a joint surface, and to collect the solder on the exposed one-side surface of the metal layer 711 by using the terminal insulating layer 714. As a result, in the first terminal 71, it is possible to improve the joint reliability with the electronic component.

(3) As shown in FIG. 7, the wiring circuit board 1 may not have a covering layer 6. The first terminal 71 has a metal layer 711, a terminal conductor layer 712, a terminal covering layer 713, and a terminal insulating layer 714.

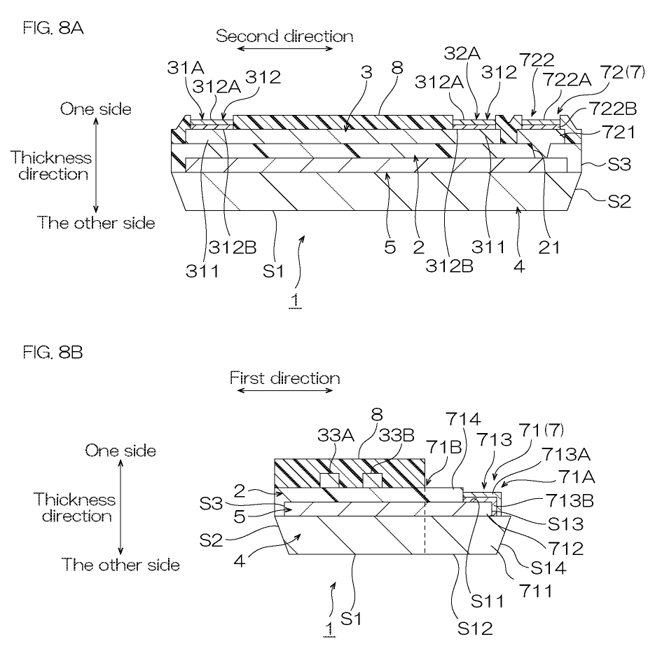

(4) As shown in FIGS. 8A and 8B, the wiring circuit board 1 may not have a covering layer 6. Furthermore, the end surface S2 of the metal support layer 4 may be discontinuous with the end surface S3 of the conductor layer 5, and the end surface S14 of the metal layer 711 may be discontinuous with the end surface S13 of the terminal conductor layer 712.

Specifically, as shown in FIG. 8A, the end surface S3 of the conductor layer 5 may be disposed separately more inwardly than the end surface S2 of the metal support layer 4 and covered by the first insulating layer 2. Further, as shown in FIG. 8B, the end surface S13 of the terminal conductor layer 712 may be disposed separately more inwardly than the end surface S14 of the metal layer 711 and covered by the terminal covering layer 713.

When the wiring circuit board 1 of this modified example is produced, in the conductor layer forming step, after a plating resist is formed in a portion where the conductor layer 5 or the terminal conductor layer 712 is not formed, a conductor layer P is formed by electrolytic plating. Thereafter, the plating resist is removed. When a joint layer is formed on the substrate M, the joint layer of the portion where the plating resist is removed is also removed.

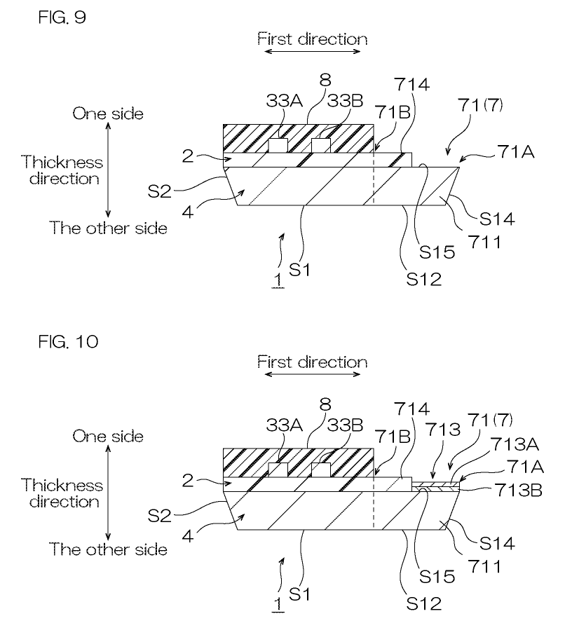

(5) As shown in FIG. 9, the wiring circuit board 1 may not include a conductor layer 5 and a covering layer 6. Furthermore, the first terminal 71 may not include a terminal conductor layer 712 and a terminal covering layer 713 while including a metal layer 711 and a terminal insulating layer 714.

The terminal insulating layer 714 covers at least a portion of the metal layer 711 in the thickness direction. The terminal insulating layer 714 covers at least a portion of the one-side surface S15 of the metal layer 711 in the thickness direction. In the thickness direction, the terminal insulating layer 714 covers at least the one-side surface S15 of the metal layer 711 at the second end 71B. In this modified example, in the thickness direction, the terminal insulating layer 714 does not cover the one-side surface S15 of the metal layer 711 at the first end 71A. At least a portion of the one-side surface S15 of the metal layer 711 in the thickness direction is exposed from the terminal insulating layer 714.

(6) As shown in FIG. 10, the wiring circuit board 1 may not include a conductor layer 5 and a covering layer 6. Furthermore, the first terminal 71 may not include a terminal conductor layer 712 while including a metal layer 711, a terminal covering layer 713, and a terminal insulating layer 714.

(7) As shown in FIG. 11, the terminal insulating layer 714 may be continuous with the second insulating layer 8. The terminal insulating layer 714 forms a single layer with the second insulating layer 8. The terminal insulating layer 714 is made of the same material as the second insulating layer 8. The thickness of the terminal insulating layer 714 may be the same as or different from the thickness of the second insulating layer 8. In this modified example, the thickness of the terminal insulating layer 714 is smaller than the total thickness of the first insulating layer 2 and the second insulating layer 8.

According to the wiring circuit board 1, as shown in FIG. 11, the terminal insulating layer 714 is continuous with the second insulating layer 8. Therefore, when an electronic component is joined in the first terminal 71, it is possible to more reliably suppress the flow of the solder toward the second end 71B side (metal support layer 4 side). As a result, in the first terminal 71, it is possible to improve the joint reliability with the electronic component.

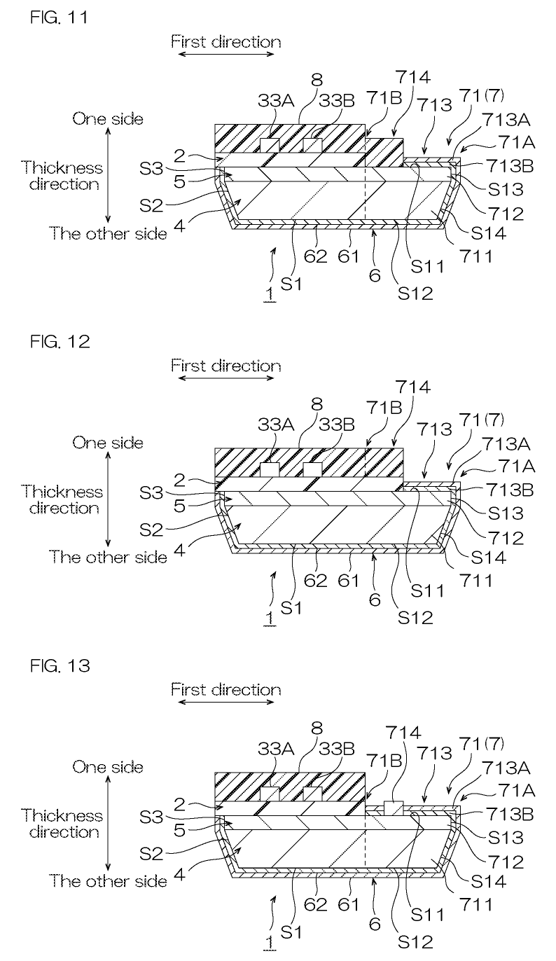

(8) As shown in FIG. 12, the terminal insulating layer 714 may be continuous with the first insulating layer 2 and the second insulating layer 8. The terminal insulating layer 714 is a laminate of the first insulating layer 2 and the second insulating layer 8. The thickness of the terminal insulating layer 714 may be the same as or different from the total thickness of the first insulating layer 2 and the second insulating layer 8. In this modified example, the thickness of the terminal insulating layer 714 is the same as the total thickness of the first insulating layer 2 and the second insulating layer 8.

According to the wiring circuit board 1, as shown in FIG. 9, the terminal insulating layer 714 is continuous with the first insulating layer 2 and the second insulating layer 8. Therefore, when an electronic component is joined in the first terminal 71, it is possible to more reliably suppress the flow of the solder toward the second end 71B side (metal support layer 4 side). As a result, in the first terminal 71, it is possible to improve the joint reliability with the electronic component.

(9) As shown in FIG. 13, the terminal insulating layer 714 may not be continuous with the first insulating layer 2 and the second insulating layer 8. The terminal insulating layer 714 is formed independently from the first insulating layer 2 and the second insulating layer 8.

In this modified example, the terminal insulating layer 714 is disposed at one side of the metal layer 711 in the thickness direction between the first end 71A and the second end 71B. Specifically, the terminal insulating layer 714 is spaced apart with respect to the first end 71A and disposed at the second end 71B side. Further, the terminal insulating layer 714 is spaced apart with respect to the second end 71B and disposed at the first end 71A side.

Further, in this modified example, in the thickness direction, the terminal insulating layer 714 does not cover the one-side surface S11 of the terminal conductor layer 712 at the first end 71A and the second end 71B. At least a portion of the one-side surface S11 of the terminal conductor layer 712 in the thickness direction is exposed from the terminal insulating layer 714.

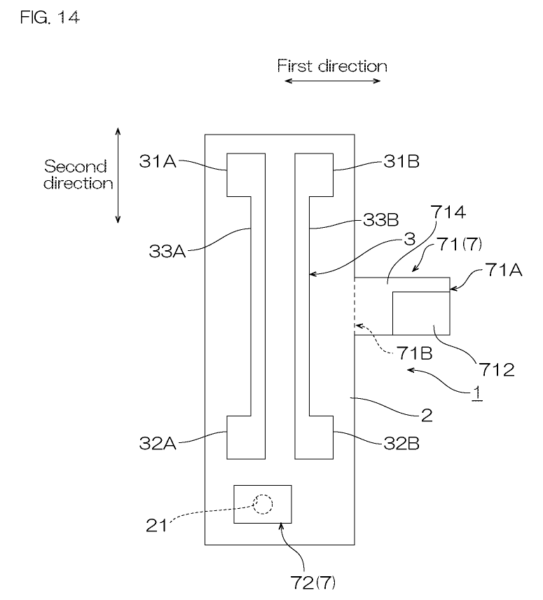

(10) As shown in FIG. 14, the terminal insulating layer 714 may have a substantially L-shape when viewed from the thickness direction. In other words, the terminal insulating layer 714 may have a substantially L-shape in a plan view.

A portion of the terminal insulating layer 714 at one side in the second direction extends toward the first end 71A. In this modified example, a portion of the terminal insulating layer 714 at one side in the second direction extends to the first end 71A.

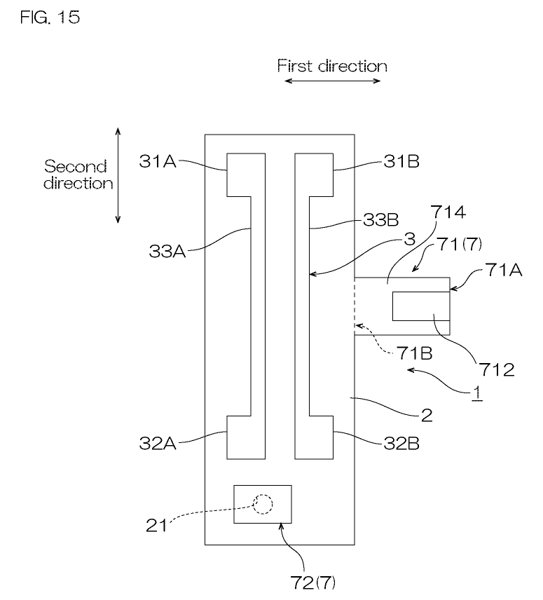

(11) As shown in FIG. 15, the terminal insulating layer 714 may have a substantially U-shape when viewed from the thickness direction. In other words, the terminal insulating layer 714 may have a substantially U-shape in a plan view.

Portions of the terminal insulating layer 714 at one side in the second direction and at the other side in the second direction extend toward the first end 71A. In this modified example, the portions of the terminal insulating layer 714 at one side in the second direction and at the other side in the second direction extend to the first end 71A.

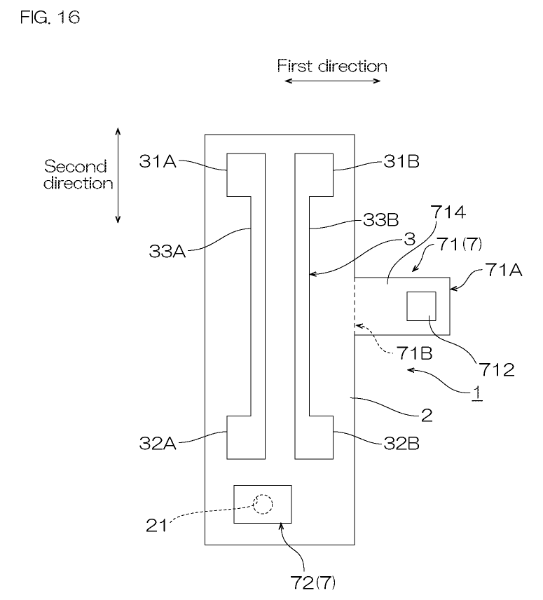

(12) As shown in FIG. 16, the terminal insulating layer 714 may have a substantially angular ring shape when viewed from the thickness direction. In other words, the terminal insulating layer 714 may have a substantially angular ring shape in a plan view. In this modified example, the terminal insulating layer 714 may have a substantially rectangular ring shape when viewed from the thickness direction.

In this modified example, the terminal insulating layer 714 covers the one-side surface S11 of the terminal conductor layer 712 at the first end 71A and the second end 71B, and has an opening portion between the first end 71A and the second end 71B. The opening portion is substantially rectangular when viewed from the thickness direction. In detail, the opening portion is a substantially square when viewed from the thickness direction.

In this modified example, the terminal covering layer 713 is not continuous with the covering layer 6.

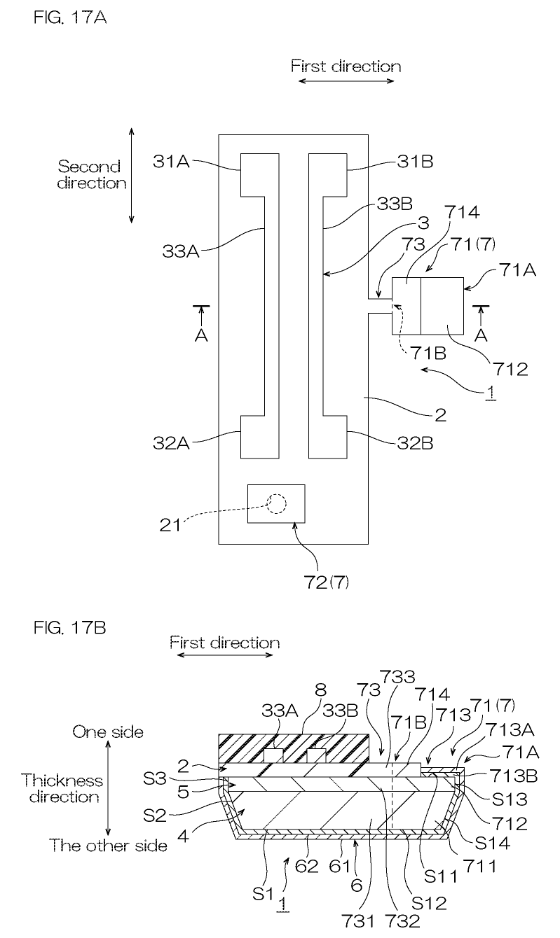

(13) As shown in FIG. 17A, the second circuit pattern 7 may include a wire portion 73. The second circuit pattern 7 includes the wire portion 73 between the first terminal 71 and the metal support layer 4.

As shown in FIG. 17B, the wire portion 73 includes a metal layer 731, a conductor layer 732, and an insulating layer 733.

The metal layer 711 of the first terminal 71 is continuous with the metal support layer 4 through the metal layer 731. In other words, the metal layer 711 of the first terminal 71 is electrically connected to the metal support layer 4 through the metal layer 731. The terminal conductor layer 712 of the first terminal 71 is continuous with the conductor layer 5 through the conductor layer 732. In other words, the terminal conductor layer 712 of the first terminal 71 is electrically connected to the conductor layer 5 through the conductor layer 732. The terminal insulating layer 714 of the first terminal 71 is continuous with the first insulating layer 2 through the insulating layer 733.

Further, the first terminal 71 and the second terminal 72 are electrically connected through the conductor layer 5 and the conductor layer 732 of the wiring portion 73.

Although not shown, when the wiring circuit board 1 does not include a conductor layer 5 and a terminal conductor layer 712, the wiring portion 73 does not include a conductor layer 732. In such a case, the first terminal 71 and the second terminal 72 is electrically connected through the metal support layer 4 and the metal layer 731 of the wiring portion 73.

(14) Also in the above-described modified examples (1) to (13), it is possible to improve the degree of freedom of the circuit design in the same manner as in the above-described embodiment.

While the illustrative embodiments of the present invention are provided in the above-described description, such is for illustrative purpose only and it is not to be construed as limiting the scope of the present invention. Modification and variation of the present invention that will be obvious to those skilled in the art is to be covered by the following claims.

### Industrial Applicability

The wiring circuit board of the present invention can be used for connecting electronic components.

### DESCRIPTION OF REFERENCE NUMERALS

1 Wiring circuit board

3 First circuit pattern

4 Metal support layer

5 Conductor layer

6 Covering layer

7 Second circuit pattern

71 First terminal

71A First end

71B Second end

72 Second terminal

711 Metal layer

712 Terminal conductor layer

713 Terminal covering laye

714 Terminal insulating layer

1. A wiring circuit board comprising:
a first insulating layer;
a first circuit pattern disposed at one side of the first insulating layer in a thickness direction of the first insulating layer;
a metal support layer disposed at an opposite side to the first circuit pattern with respect to the first insulating layer in the thickness direction, insulated from the first circuit pattern by the first insulating layer, and supporting the first circuit pattern and the first insulating layer; and
a second circuit pattern independent from the first circuit pattern,
wherein the second circuit pattern includes a first terminal,
wherein the first terminal includes: a metal layer continuous with the metal support layer; and a terminal insulating layer disposed at one side of the metal layer in the thickness direction,
wherein the first terminal includes: a first end disposed away from the metal support layer; and a second end disposed between the first end and the metal support layer, and
wherein the terminal insulating layer is disposed between the first end and the second end.

2. The wiring circuit board according to claim 1,
wherein in the thickness direction, the terminal insulating layer is disposed at least at one side of the metal layer at the second end.

3. The wiring circuit board according to claim 1,
wherein the terminal insulating layer is continuous with the first insulating layer.

4. The wiring circuit board according to claim 1, further comprising:
a second insulating layer covering at least a portion of the first circuit pattern,
wherein the terminal insulating layer is continuous with the second insulating layer.

5. The wiring circuit board according to claim 4,
wherein the terminal insulating layer is continuous with the first insulating layer and the second insulating layer.

6. The wiring circuit board according to claim 1,
wherein the terminal insulating layer covers at least the metal layer at the second end, and
wherein at least a portion of a one-side surface of the metal layer in the thickness direction is exposed from the terminal insulating layer.

7. The wiring circuit board according to claim 1,
wherein the first terminal further includes a terminal covering layer that is made of metal and covers at least a portion of the metal layer.

8. The wiring circuit board according to claim 7,
wherein the terminal insulating layer covers at least the metal layer at the second end, and
wherein the terminal covering layer covers a rest of the metal layer.

9. The wiring circuit board according to claim 7,
wherein a thickness of the terminal insulating layer is larger than a thickness of the terminal covering layer.

10. The wiring circuit board according to claim 1, further comprising
a conductor layer disposed between the first insulating layer and the metal support layer in the thickness direction.

11. The wiring circuit board according to claim 10,
wherein the first terminal further includes a terminal conductor layer continuous with the conductor layer.

12. The wiring circuit board according to claim 11,
wherein the terminal insulating layer covers at least the terminal conductor layer at the second end, and
wherein at least a portion of a one-side surface of the terminal conductor layer in the thickness direction is exposed from the terminal insulating layer.

13. The wiring circuit board according to claim 11,
wherein the first terminal further includes a terminal covering layer that is made of metal and covers at least a portion of the terminal conductor layer.

14. The wiring circuit board according to claim 13,
wherein the terminal insulating layer covers at least the terminal conductor layer at the second end, and
wherein the terminal covering layer covers a rest of the terminal conductor layer.

15. The wiring circuit board according to claim 13,
wherein a thickness of the terminal insulating layer is larger than a thickness of the terminal covering layer.
